(19) United States
(12) Patent Application Publication
(10) Pub. No.: US 2025/0275162 A1
(43) Pub. Date: Aug. 28, 2025

(54) ELECTRONIC COMPONENT

(71) Applicant: STMicroelectronics International N.V., Geneva (CH)

(72) Inventors: Christophe MAURIAC, Montbazon (FR); Laurent SIEGERT, LA MEMBROLLE SUR CHOISILLE (FR)

(21) Appl. No.: 19/049,163

(22) Filed: Feb. 10, 2025

(30) Foreign Application Priority Data
Feb. 28, 2024 (FR) FR2401932

(51) Int. Cl. H10D 18/80; H10D 18/01

(52) U.S. Cl. CPC H10D 18/80; H10D 18/021

(57) ABSTRACT

Electronic components, more particularly triacs, are provided. An example triac is formed inside and on top of a semiconductor substrate. The triac comprising: on the side of a first surface of the substrate, a first doped region of a first conductivity type and connected to a first conduction terminal; on the side of a second surface of the substrate opposite to the first surface, a second doped region of the first conductivity type and connected to a second conduction terminal; and a gate region connected to a control terminal. The first and second regions respectively have first and second parallel lateral surfaces. Between the first and second parallel lateral surfaces is a separation region not covered by the first and second regions, the separation region shaped as a strip extending along a first direction inside of the gate region and exhibiting an inflection outside of the gate region.

### CROSS REFERENCE TO RELATED APPLICATIONS

This application claims the priority benefit of French patent application number 24/01932, filed on Feb. 28, 2024, entitled “Composant électronique,” which is hereby incorporated by reference to the maximum extent allowable by law.

### TECHNICAL FIELD

The present disclosure generally concerns electronic components, more particularly triacs.

### BACKGROUND

Many electronic components have been provided. Among these electronic components, triacs (triodes for alternating current) have more particularly been provided.

However, existing electronic components, in particular existing triacs, suffer from various disadvantages.

### BRIEF SUMMARY

There exists a need to overcome all or part of the disadvantages of existing electronic components, in particular of triacs.

For this purpose, an embodiment provides a triac formed inside and on top of a semiconductor substrate, the triac comprising:
on the side of a first surface of the substrate, a first doped region of a first conductivity type and connected to a first conduction terminal of the triac;
   on the side of a second surface of the substrate opposite to the first surface, a second doped region of the first conductivity type and connected to a second conduction terminal of the triac; and
a gate region connected to a control terminal of the triac, wherein the first and second regions respectively have first and second parallel lateral surfaces, the triac comprising, between the first and second parallel lateral surfaces, a separation region not covered by the first and second regions, the separation region having the shape of a strip extending along a first direction inside of the gate region and exhibiting an inflection outside of the gate region.

According to an embodiment, the triac has, in top view, a substantially rectangular shape.

According to an embodiment, the first direction is inclined by an angle equal to approximately 45° with respect to the sides of the rectangle formed by the triac.

According to an embodiment, the separation region has, outside of the gate region, the shape of a strip extending along a second direction substantially parallel to a diagonal of the rectangle formed by the triac.

According to an embodiment, a shorting network is formed in each of the first and second regions, each shorting network comprising at least one through trench extending along a third direction inside of the gate region and exhibiting an inflection outside of the gate region.

According to an embodiment, the third direction is substantially parallel to the first direction.

According to an embodiment, outside of the gate region, each through trench extends along a fourth direction substantially parallel to a diagonal of the rectangle formed by the triac.

According to an embodiment, each shorting network further comprises a plurality of through vias.

According to an embodiment, the gate region has, in top view, a substantially square shape.

According to an embodiment, the semiconductor substrate is doped with a second conductivity type opposite to the first conductivity type, the first and second conductivity types respectively being type N and type P.

An embodiment provides a device comprising at least one triac as described.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 is a simplified and partial side and cross-section view of an example of a triac according to an embodiment;

FIG. 2 is an equivalent electric diagram of the triac of FIG. 1;

FIG. 3 is a simplified and partial top view of an example of a triac according to an embodiment;

FIG. 4 is a simplified and partial top view of another example of a triac according to an embodiment; and

FIG. 5 is a block diagram illustrating, schematically and partially, an example of a device comprising the triac of FIG. 4 according to an embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for the understanding of the described embodiments have been illustrated and described in detail. In particular, the applications of triacs have not been detailed, the described embodiments being compatible with all or most applications of triacs, subject to possible adaptations within the abilities of those skilled in the art on reading of the present disclosure.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “front”, “back”, “top”, “bottom”, “left”, “right”, etc., or relative positions, such as terms “above”, “below”, “higher”, “lower”, etc., or to terms qualifying directions, such as terms “horizontal”, “vertical”, etc., it is referred, unless specified otherwise, to the orientation of the drawings.

Unless specified otherwise, the expressions “around”, “approximately”, “substantially”, and “in the order of” signify within 10%, preferably within 5%, or, in the case of angular values, within 10°, preferably within 5°.

In the following description, the terms “insulating” and “conductive” respectively mean, unless specified otherwise, electrically insulating and electrically conductive.

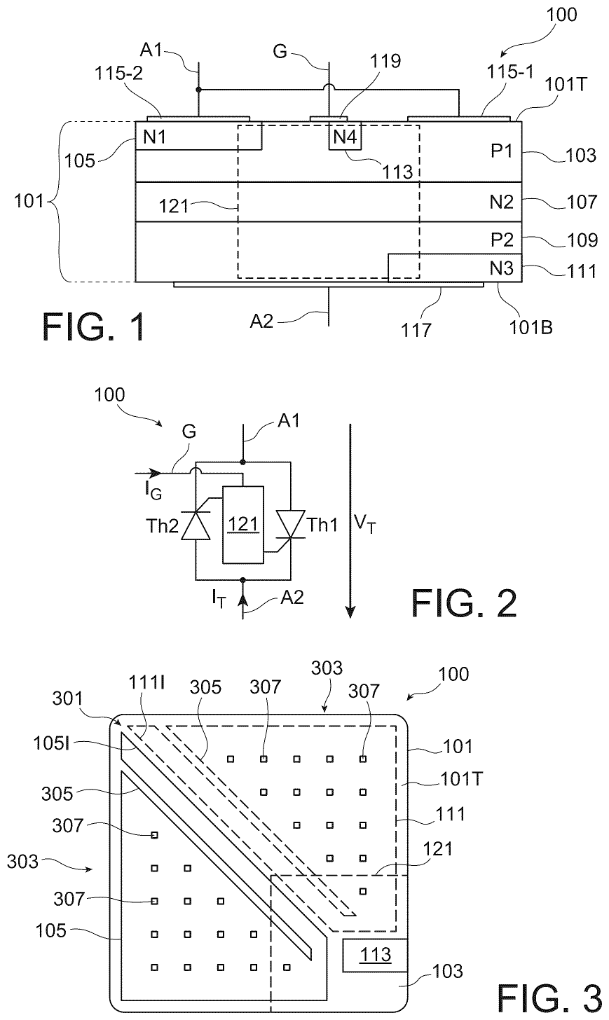

FIG. 1 is a simplified and partial side and cross-sectional view of an example of a triac (triode for alternating current) 100 according to an embodiment.

In the shown example, triac 100 is formed inside and on top of a semiconductor substrate 101. Substrate 101 is, for example, a wafer or a piece of wafer made of a semiconductor material, for example, silicon.

In the illustrated example, triac 100 comprises a doped semiconductor region 103 (P1) of a first conductivity type, for example type P, formed in semiconductor substrate 101. In this example, region 103 extends across the thickness of semiconductor substrate 101 from a surface 101T of semiconductor substrate 101 (the upper surface of semiconductor substrate 101, in the orientation of FIG. 1).

In the shown example, triac 100 further comprises, on the side of surface 101T of semiconductor substrate 101, a doped semiconductor region 105 (N1) of a second conductivity type opposite to the first conductivity type, that is, N-type doped, in this example. Region 105 is formed in region 103 and extends across the thickness of semiconductor substrate 101 from its surface 101T down to a depth smaller than that of region 103. In the shown example, region 105 is thus at least partially surrounded, or bordered, by region 103. In the orientation of FIG. 1, the material of region 103 coats at least certain lateral surfaces and a lower surface, or a bottom, of region 105.

In the shown example, triac 100 further comprises another doped semiconductor region 107 (N2) of the second conductivity type, that is, N-type doped, in this example. In this example, region 107 is located on the side of a surface of region 103 opposite to surface 101T of semiconductor substrate 101 (on the lower surface side of region 103, in the orientation of FIG. 1). In the shown example, region 107 is located under and in contact with region 103.

In the shown example, triac 100 further comprises another doped semiconductor region 109 (P2) of the first conductivity type, that is, P-type doped, in this example. In this example, region 109 is located on the side of a surface of region 107 opposite to region 103 (on the lower surface side of region 107, in the orientation of FIG. 1). In the shown example, region 109 is located under and in contact with region 107. In the shown example, region 109 extends vertically across the thickness of semiconductor substrate 101 from another surface 101B of semiconductor substrate 101 opposite to surface 101T (the lower surface of semiconductor substrate 101, in the orientation of FIG. 1).

In the shown example, triac 100 further comprises, on the side of surface 101B of semiconductor substrate 101, still another doped semiconductor region 111 (N3) of the second conductivity type, that is, N-type doped, in this example. Region 111 is formed in region 109 and extends across the thickness of semiconductor substrate 101 from its surface 101B down to a depth smaller than that of region 109. In the shown example, region 111 is thus at least partially surrounded, or bordered, by region 109. In the orientation of FIG. 1, the material of region 109 coats at least certain lateral surfaces and an upper surface of region 111. In the shown example, region 111 is not located vertically in line with region 105.

In the shown example, triac 100 further comprises another doped semiconductor region 113 (N4) of the second conductivity type, that is, N-type doped, in this example. Region 113 is formed in region 103 and extends across the thickness of semiconductor substrate 101 from its surface 101T down to a depth smaller than that of region 103. Region 113 is separate from region 105 and has, for example, a height, or depth, substantially equal to that of region 105. In the shown example, region 113 is thus at least partially surrounded, or bordered, by region 103. In the orientation of FIG. 1, the material of region 103 coats all the lateral surfaces and a lower surface, or a bottom, of region 113. In the shown example, region 113 is not located vertically in line with region 111. However, this example is not limiting and region 113 may, as a variant, be located vertically in line with region 111.

As an example, semiconductor substrate 101 is doped with the first conductivity type, that is, type P, in this example, and regions 105, 107, 111, and 113 are formed by diffusion, in semiconductor substrate 101, of doping species of the second conductivity type, that is, type N, in this example.

In the shown example, triac 100 comprises a first conduction terminal, also called first anode (A1), connected to regions 103 and 105. In this example, conduction terminal A1 comprises an electrode 115-1 laterally extending on top of and in contact with a portion of the surface of region 103 flush with surface 101T of semiconductor substrate 101 (the upper surface of region 103, in the orientation of FIG. 1). Conduction terminal A1 for example further comprises another electrode 115-2 laterally extending on top of and in contact with a portion of the surface of region 105 flush with surface 101T of semiconductor substrate 101 (the upper surface of region 105, in the orientation of FIG. 1). Electrodes 115-1 and 115-2 are for example separate and electrically interconnected by an external circuit. As a variant, electrodes 115-1 and 115-2 may form a single electrode.

In the shown example, triac 100 further comprises a second conduction terminal, also called second anode (A2), connected to regions 109 and 111. In this example, conduction terminal A2 comprises an electrode 117 laterally extending on top of and in contact with a portion of the surface of region 109 flush with surface 101B of semiconductor substrate 101 (the lower surface of region 109, in the orientation of FIG. 1). Electrode 117 further extends on top of and in contact with a portion of the surface of region 111 flush with surface 101B of semiconductor substrate 101 (the lower surface of region 111, in the orientation of FIG. 1).

In the shown example, triac 100 further comprises a gate terminal (G) connected to regions 103 and 113. In this example, gate terminal G comprises an electrode 119 laterally extending on top of and in contact with a portion of the surface of region 103 flush with surface 101T of semiconductor substrate 101 (the upper surface of region 103, in the orientation of FIG. 1). Electrode 119 further extends on top of and in contact with a portion of the surface of region 113 flush with surface 101T of semiconductor substrate 101 (the upper surface of region 113, in the orientation of FIG. 1).

As an example, electrodes 115-1, 115-2, 117, and 119 are each made of a conductive material, for example a metal or a metal alloy. Further, each electrode 115-1, 115-2, 117, 119 may have a single-layer or multi-layer structure.

In the shown example, triac 100 comprises a gate region 121 symbolized by a dotted rectangle in FIG. 1. The gate region 121 of triac 100 extends in semiconductor substrate 101 substantially vertically in line with the electrode 119 of gate terminal G, under region 113. In the illustrated example, the gate region 121 comprises a gate of the triac 100, comprising for example parts of the semiconductor regions 103 and 113 located vertically in line with the electrode 119, and a primary triggering area of the triac 100. In this example, the primary triggering area of the triac 100 extends laterally from the gate and extends vertically, from the gate, to the electrode 117.

FIG. 2 shows an equivalent electrical diagram of the triac 100 of FIG. 1.

In the shown example, triac 100 is symbolized by two thyristors Th1 and Th2 assembled head-to-tail in parallel between conduction terminals A1 and A2. In the diagram of FIG. 2, thyristors Th1 and Th2 have gate terminals connected, by gate region 121, to gate terminal G.

Thyristor Th1 for example comprises a stack comprising portions of regions 103, 107, 109, and 111 located substantially vertically in line with electrode 115-1 (on the right-hand side of gate region 121, in the orientation of FIG. 1). Electrodes 115-1 and 117 for example respectively form anode and cathode electrodes of thyristor Th1.

Similarly, thyristor Th2 for example comprises a stack comprising portions of regions 105, 103, 107, and 109 located substantially vertically in line with electrode 115-2 (on the left-hand side of gate region 121, in the orientation of FIG. 1). Electrodes 115-2 and 117 for example respectively form cathode and anode electrodes of thyristor Th2.

In the example shown in FIG. 2, a voltage VT is present between the conduction terminals A2 and A1 of triac 100. Voltage VT is for example applied by an electric power source external to triac 100, not shown in FIG. 2. Further, in this example, a control or gate current IG flows from gate terminal G to gate region 121.

When control current IG is substantially zero, triac 100 is in an off state, preventing the flowing of a current IT between its conduction terminals A2 and A1.

From the off state, when control current IG becomes greater, in absolute value, than a gate threshold current IGT, for example under the effect of the application of a control current pulse IG, triac 100 then switches to an on state. In the on state, current IT is free to flow between conduction terminals A2 and A1. When control current IG becomes lower again than gate threshold current IGT, for example at the end of the pulse of control current IG, triac 100 remains in the on state as long as current IT remains, in absolute value, greater than a latching current IL of triac 100. In particular, if the pulse of control current IG lasts for a duration sufficient to enable triac 100 to complete its switching to the on state, for example a duration in the order of a few tens of microseconds, then latching current IL has a minimum value corresponding to a holding current IH. Holding current IH corresponds to the minimum value of current IT required to hold triac 100 in the on state.

When current IT becomes smaller, in absolute value, than holding current IH, triac 100 then switches from the on state to the off state.

In practice, the gate threshold IGT, latching IL, and holding IH currents may, in absolute values, take different values according to whether control current IG is positive or negative, and/or to whether voltage VT is positive or negative.

Triac 100 has a sensitivity depending on the value of its gate threshold current IGT. The lower gate threshold current IGT is, the more sensitive triac 100 is said to be.

The electrical performance of triac 100 further depends on various other parameters, designated with the expressions dv/dt, di/dt, (di/dt) c, etc. These parameters are closely related to the characteristics, in particular to the geometry and to the dimensions, of gate region 121. In other words, slight changes to gate region 121 cause significant changes in the electrical performance of triac 100.

FIG. 3 is a simplified and partial top view of triac 100. In the shown example, triac 100 has a substantially square general shape. As an example, the square formed by triac 100 has a side length in the order of a few millimeters, for example equal to approximately 2 or 3 mm. Triac 100 is for example capable of withstanding, in the on state, a nominal current in the order of from 16 to 20 A.

In the shown example, semiconductor region 105 and semiconductor region 111 have, in top view, substantially equal surface areas. This enables, in particular, to ascertain that thyristors Th1 and Th2 have substantially identical electrical characteristics.

Further, in this example, regions 105 and 111 do not overlap, that is, region 105 does not extend laterally vertically in line with region 111. This particularly enables to ascertain that thyristors Th1 and Th2 can be controlled independently from each other.

As an example, each region 105, 111 has a surface area equal to approximately half a surface area corresponding to the total surface area of triac 100 minus the surface area of region 113. In the shown example where triac 100 has a square general shape, regions 105 and 111 for example each have a substantially triangular general shape.

In the shown example, gate region 121, symbolized in FIG. 3 by a dotted square surrounding semiconductor region 113, is located in the vicinity of a first corner of the square formed by triac 100 (the right-hand bottom corner, in the orientation of FIG. 3). Gate region 121 comprises region 113 and portions of regions 105 and 111 located in the vicinity of the first corner.

In the shown example, regions 105 and 111 respectively have parallel lateral surfaces 105I and 111I. Surfaces 105I and 111I are for example substantially vertical. In this example, triac 100 comprises, between the parallel lateral surfaces 105I and 111I, not covered with regions 105 and 111. In other words, region 301 does not extend vertically in line with regions 105 and 111.

In the shown example, separation region 301 has the shape of a substantially rectilinear strip extending along a direction substantially parallel to a diagonal of the square formed by triac 100. In the shown example, separation region 301 more precisely extends along a diagonal of the square formed by triac 100 connecting the first corner to a second corner of the square, diagonally opposite to the first corner. In this example, the lateral surfaces 105I and 111I of regions 105 and 111 are, in top view, inclined by an angle equal to approximately 45° with respect to the sides of the square formed by triac 100, the direction along which separation region 301 extends being inclined by an angle equal to approximately 45° with respect to the sides of the square.

In the shown example, a shorting network 303 is formed in each of regions 105, 111. As an example, each network 303 comprises at least one trench 305 formed in region 105 or 111. In the shown example, each trench 305 is a through trench, that is, it extends through the entire thickness of the region 105, 111 in which it is formed.

In the shown example, region 105 comprises a trench 305 laterally extending along a direction substantially parallel to side 105I of region 105. Similarly, region 111 comprises, in this example, a trench 305 laterally extending along a direction substantially parallel to side 111I of region 111. In the shown example, each trench 305 is substantially rectilinear along its entire length. In the shown example, each trench 305 extends along a direction inclined by an angle equal to approximately 45° with respect to the sides of the square formed by triac 100. Each trench 305 may, as in the example shown in FIG. 3, emerge onto a side of region 105 or 111 different from side 105I or 111I, for example in the vicinity of the second corner of the square formed by triac 100.

Each network 303 for example further comprises vias 307 formed in region 105 or 111. In the shown example, each via 307 is a through via, that is, it extends across the entire thickness of the region 105, 111 in which it is formed. In the shown example, vias 307 are organized in an array of rows and columns, for example with a constant pitch, that is, with a constant center-to-center distance between two adjacent vias 307. Vias 307 may have any cross-section shape, for example rectangular, oval, square, circular, etc.

In the shown example, each trench 305 and via 307 is filled with the material of region 103, for the trench(es) 305 and the via(s) 307 formed in region 105, or with the material of region 109, for the trench(es) 305 and the via(s) 307 formed in region 111.

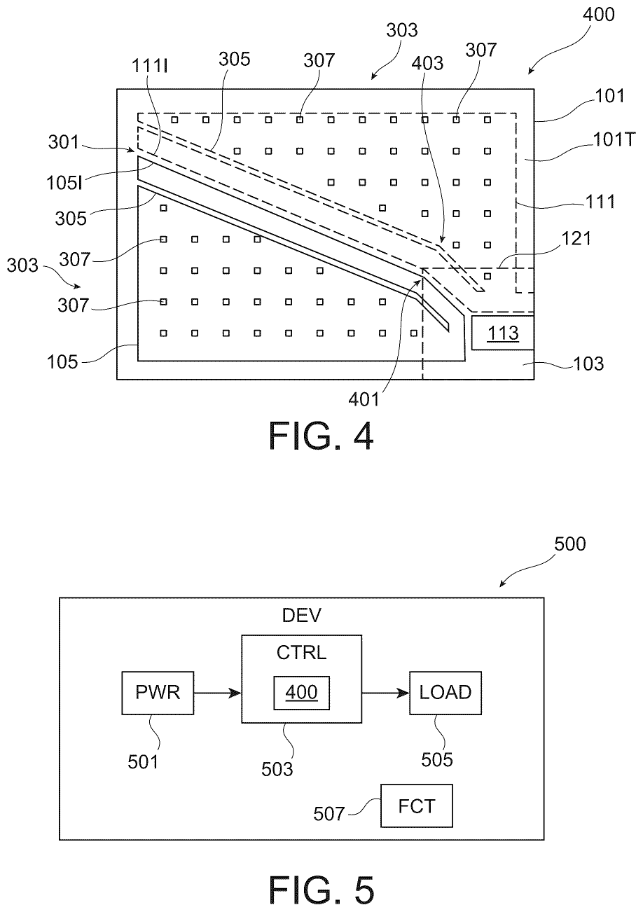

FIG. 4 is a simplified and partial top view of another example of a triac 400 according to an embodiment.

The triac 400 of FIG. 4 comprises elements in common with the triac 100 of FIG. 3. These common elements will not be detailed again hereafter.

The triac 400 of FIG. 4 differs from the triac 100 of FIG. 3 in that, according to an embodiment, the separation region 301 of triac 400 exhibits an inflection 401 outside of gate region 121. According to this embodiment, the separation region 301 of triac 400 has the shape of a strip extending along a first direction, inside of gate region 121, and extending along a second direction, non-colinear to the first direction, outside of gate region 121.

In the shown example, triac 400 has a substantially rectangular general shape. In this example, the first direction is inclined by an angle substantially equal to 45° with respect to the sides of the rectangle formed by triac 400, and the second direction is substantially parallel to a diagonal of the rectangle formed by triac 400. In the shown example, the second direction is substantially parallel to the diagonal coupling a first corner of the rectangle formed by triac 400, in the vicinity of which region 113 is located, to a second corner diagonally opposite to the first corner.

Further, in this example, the trenches 305 formed in regions 105 and 111 extend along a third direction, inside of gate region 121, and exhibiting an inflection 403 outside of gate region 121. In the shown example, trenches 305 extend along a fourth direction, non-colinear with the third direction, outside of gate region 121. The third and fourth directions are, for example, respectively parallel to the first and second directions. In the shown example, the third direction is inclined by an angle substantially equal to 45° with respect to the sides of the rectangle formed by triac 400, and the fourth direction is substantially parallel to the diagonal coupling the first and second corners of the rectangle formed by triac 400.

An advantage of triac 400 lies in the fact that inflection 401 enables not to modify the structure of gate region 121 with respect to triac 100. Triac 400 thus for example has electrical characteristics identical or similar to those of triac 100. As an example, triac 400 has a gate threshold current IGT, a latching current IL, and a hold current IH substantially equal to those of triac 100. Triac 400 for example further has a dynamic performance, characterized by parameters dv/dt, di/dt, (di/dt) c, etc., substantially equal to that of triac 100. In terms of electrical characteristics, triac 400 for example differs from triac 100 in that triac 400 has a larger rating than triac 100, triac 400 being, in this case, capable of withstanding a higher rated current than triac 100.

Inflection 401 further advantageously enables to keep semiconductor regions 105 and 111 having substantially equal surface areas, and thus thyristors Th1 and Th2 having substantially identical electrical characteristics.

FIG. 5 is a block diagram, schematically and partially illustrating example of a device 500 (DEV) comprising the triac 400 of FIG. 4 according to an embodiment.

In the shown example, device 500 comprises an electrical power source 501 (PWR). Electrical power source 501 is obtained, for example, by connecting device 500 to an electrical power distribution network, for example a single-phase or three-phase AC distribution network. As a variant, electrical power source 501 may be a battery embedded in device 500, source 501 then for example supplying a DC current. In this case, the current supplied by source 501 is for example converted into an AC current by an inverter (not shown in FIG. 5).

In the shown example, device 500 further comprises a control circuit 503 (CTRL) comprising triac 400. Although a single triac 400 has been symbolized in FIG. 5, control circuit 503 may of course comprise at least one other triac similar or identical to triac 400. In the shown example, control circuit 503 is connected to electrical power source 501. In practice, triac 400 is, for example, packaged and soldered to a printed circuit board of control circuit 503.

Device 500 for example further comprises a load 505 (LOAD) coupled or connected to control circuit 503. Load 505 may correspond to any type of element called electrical power receiver or consumer. As an example, load 505 is a rotating machine, for example an electric motor, a heating resistor, etc.

Control circuit 503 is for example intended to control the power supply of load 505 from electrical power source 501. As an example, according to the needs of a user of device 500, control circuit 503 is intended to authorize or block the supply of electrical power to load 505 from source 501.

As an example, triac 400 is used in applications:
of lighting control, for example to control the brightness of incandescent and dimmable LED lights, for example in street lighting, stage lighting and other types of commercial lighting systems;
of heating control, for example to control the temperature of heaters, ovens and other heating systems;
of motor control, for example to control the speed of AC motors in various industrial applications;
of power supply, for example to control output voltages and currents of AC power supply systems;
in the medical field, triac 400 being, for example, integrated into medical equipment such as electrocautery devices and defibrillators;
in the field of home automation, triac 400 being, for example, integrated into home automation systems to control various appliances such as air conditioners, fans and refrigerators.

An advantage of triac 400 is that it enables to be used to replace triac 100 without modifying the electrical characteristics of its gate region 121. This for example enables to provide a plurality of variants of device 500 according to the electrical power of the load 505 to be powered, for example a so-called “low-power” version where control circuit 503 uses triac 100, and a so-called “high-power” version where control circuit 503 uses triac 400, without modifying the other elements of control circuit 503.

Device 500 may further comprise other elements and/or circuits symbolized, in FIG. 5, by a single functional block 507 (FCT).

Various embodiments and variants have been described. Those skilled in the art will understand that certain features of these various embodiments and variants may be combined, and other variants will occur to those skilled in the art. In particular, although FIG. 4 takes as an example a case where triac 400 has a rectangular general shape, the embodiments are not limited to this case and more generally apply to any triac shape, for example oval, circular, hexagonal, octagonal, etc.

Finally, the practical implementation of the described embodiments and variants is within the abilities of those skilled in the art based on the functional indications given hereabove. In particular, the described embodiments are not limited to the specific examples of materials and of dimensions mentioned in the present disclosure.

1. A triac formed inside and on top of a semiconductor substrate, the triac comprising:
on the side of a first surface of the substrate, a first doped region of a first conductivity type and connected to a first conduction terminal of the triac;
on the side of a second surface of the substrate opposite to the first surface, a second doped region of the first conductivity type and connected to a second conduction terminal of the triac; and
a gate region connected to a control terminal of the triac,
wherein the first doped region and the second doped region respectively have first and second parallel lateral surfaces, the triac comprising, between the first and second parallel lateral surfaces, a separation region not covered by the first doped region and the second doped region, the separation region having a shape of a strip extending along a first direction inside of the gate region and exhibiting an inflection outside of the gate region.

2. The triac of claim 1, the triac having, in top view, a substantially rectangular shape.

3. The triac of claim 2, wherein the first direction is inclined by an angle equal to approximately 45° with respect to one or more sides of the substantially rectangular shape formed by the triac.

4. The triac of claim 2, wherein the separation region has, outside of the gate region, the shape of a strip extending along a second direction substantially parallel to a diagonal of the substantially rectangular shape formed by the triac.

5. The triac of claim 2, wherein a shorting network is formed in each of the first doped region and the second doped region, each shorting network comprising at least one through trench extending along a third direction inside of the gate region and exhibiting an inflection outside of the gate region.

6. The triac of claim 5, wherein the third direction is substantially parallel to the first direction.

7. The triac of claim 5, wherein, outside of the gate region, each through trench extends along a fourth direction substantially parallel to a diagonal of the substantially rectangular shape formed by the triac.

8. The triac of claim 5, wherein each shorting network further comprises a plurality of through vias.

9. The triac of claim 1, wherein the gate region has, in top view, a substantially square shape.

10. The triac of claim 1, wherein the semiconductor substrate is doped with a second conductivity type opposite to the first conductivity type, the first and second conductivity types respectively being type N and type P.

11. A device comprising at least one triac of claim 1.
